(19) United States
(12) Patent Application Publication
(10) Pub. No.: US 2025/0016962 A1
(43) Pub. Date: Jan. 9, 2025

(54) HIGHLY THERMALLY CONDUCTIVE HYBRID THERMAL INTERFACE MATERIAL

(71) Applicant: Honeywell International Inc., Charlotte, NC (US)

(72) Inventors: Yaqun Liu, Hangzhou (CN); Qian Yang, Shanghai (CN); Jin Chang, Shanghai (CN); Kai Wang, Shanghai (CN)

(21) Appl. No.: 18/741,727

(22) Filed: Jun. 12, 2024

Related U.S. Application Data
(60) Provisional application No. 63/524,404, filed on Jun. 30, 2023.

(51) Int. Cl. H05K 7/20; C09K 5/14

(52) U.S. Cl. CPC H05K 7/20463; C09K 5/14; H05K 7/20409

(57) ABSTRACT

A thermal interface material including at least a diamond-containing filler; a silicone oil, as well as a plurality of additives.

### CROSS-REFERENCE TO RELATED APPLICATIONS

This application claims the benefit under 35 U.S.C. § 119(e) of U.S. Provisional Application No. 63/524,404 entitled “HIGHLY THERMALLY CONDUCTIVE HYBRID THERMAL INTERFACE MATERIAL,” filed on Jun. 30, 2023, which is herein incorporated by reference in its entirety.

### FIELD

The present disclosure generally relates to thermal interface materials, and more particularly, to thermal interface materials that have high thermal conductivity.

### BACKGROUND

Thermal interface materials (TIMs) are widely used to dissipate heat from electronic components, such as central processing units, video graphics arrays, servers, game consoles, smart phones, LED boards, and the like. Thermal interface materials are typically used to transfer excess heat from the electronic component to a heat spreader, such as a heat sink.

Thermally conductive TIMs are a gel-like thermally conductive material traditionally made of silica gel composite and thermally conductive fillers. These TIMs exhibit low thermal resistance, the ability to be formed/shaped on heat dissipation components and automatically fill gaps, provide insulation, maximize the limited contact area, and are infinitely compressible.

As the integration of integrated circuits is getting more common, the size of circuits is getting smaller, and the heat generation is getting bigger. In order to dissipate a large amount of heat, thermally conductive materials with high thermal conductivity are required. Thermal pads, which can have high thermal conductivities may be quite thick and not compressible. Because of the thickness of thermal pads, they may not accommodate smaller circuits. Most known thermally conductive TIMs, while compressible to accommodate small circuits, have lower thermal conductivities. As such, there is a need for a TIM composition with an increased thermal conductivity.

### SUMMARY

The present disclosure provides compositions for a thermal interface material, including a diamond-containing filler, a silicone oil, and a plurality of additives.

The present disclosure also provides a method for applying a thermal interface material to a substrate. The method includes combining each of a conductive filler, a silicone oil, and a plurality of additives to form the thermal interface material, the conductive filler including a blended diamond filler, and applying the thermal interface material to a metal substrate.

The present disclosure further provides an electronic component including a heat sink, an electronic chip, and a thermal interface material positioned between the heat sink and the electronic chip. The thermal interface material includes a conductive filler, the conductive filler including a blended diamond filler, silicone oil, and a plurality of additives.

### BRIEF DESCRIPTION OF THE DRAWINGS

The above-mentioned and other features and advantages of this disclosure, and the manner of attaining them, will become more apparent and the invention itself will be better understood by reference to the following description of embodiments of the invention taken in conjunction with the accompanying drawings, wherein:

FIG. 1A schematically illustrates an electronic chip, a heat spreader, a heat sink, and first and second thermal interface materials;

FIG. 1B schematically illustrates an exemplary thermal interface material positioned between an electronic chip and a heat sink;

FIG. 1C schematically illustrates an exemplary thermal interface material positioned between a heat spreader and a heat sink;

FIG. 1D schematically illustrates an exemplary thermal interface material positioned between an electronic chip and a heat spreader;

FIG. 2A illustrates the vertical stability of comparative composition 1;

FIG. 2B illustrates the vertical stability of inventive composition 1; and

FIG. 2C illustrates the vertical stability of inventive composition 2.

Corresponding reference characters indicate corresponding parts throughout the several views. The exemplifications set out herein illustrate exemplary embodiments of the invention and such exemplifications are not to be construed as limiting the scope of the invention in any manner.

### DETAILED DESCRIPTION

The present invention relates to thermal interface materials useful in transferring heat away from electronic components. Specifically, the present invention relates to high thermal conductivity thermal interface materials, which include a relatively high weight percent of diamond filler, useful in transferring heat away from electronic components.

### I. Thermal Interface Material Composition:

The present invention relates to thermal interface materials (TIMs) useful in transferring heat away from electronic components, which exhibit high thermal conductivity compared to traditional TIMs. The thermal interface material composition of the present disclosure may include a diamond-containing filler, a silicone oil, and a plurality of additives. The thermal interface material may be surfactant-free and emulsion agent-free. In some exemplary embodiments, the TIM is prepared by combining the individual components in a heated mixer and blending the composition together. The blended composition may then be applied directly to the substrate, such as in a stencil-printing process.

### A. Diamond-Containing Filler

The thermal interface material composition may include a diamond-containing filler. The diamond-containing filler may increase the thermal conductivity of the thermal interface material while decreasing any sedimentation when forming the TIM composition.

Exemplary diamond-containing filler can include any one of, or combination of, diamond, metal oxides, and/or ceramics. The metal oxide or ceramics can include, but not limited to, alumina (aluminum oxide), aluminum nitride, boron nitride, zinc oxide, and tin oxide.

One component of the diamond-containing filler may be zinc oxide. The zinc oxide may have a D50 particle size from 0.45 μm, 0.50 μm to 0.55 μm, 0.60 μm, 0.65 μm or within any range using any two of the foregoing as endpoints, such as 0.45 μm to 0.65 μm, or 0.50 μm to 0.60 μm, as measured by a Mastersizer 3000 Laser particle size analyzer. The diamond-containing filler may comprise a weight percent of zinc oxide, for example, from 0.2 wt. %, 0.5 wt. %, 1.0 wt. % to 1.5 wt. %, 2.0 wt. %, 2.5 wt. %, or within any range using any two of the foregoing as endpoints, such as 0.2 wt. % to 2.5 wt. %, 0.5 wt. % to 2.0 wt. %, or 1.0 wt. % to 1.5 wt. %, where wt. % is based on the total weight of the diamond-containing filler.

One component of the diamond-containing filler may be aluminum oxide (D50 2-5 μm). The aluminum oxide may have a D50 particle size from 2 μm, 3 μm to 4 μm, 5 μm or within any range using any two of the foregoing as endpoints, such as 2 μm to 5 μm, or 3 μm to 4 μm, as measured by a Mastersizer 3000 Laser particle size analyzer. The diamond-containing filler may comprise a weight percent of aluminum oxide (D50 2-5 μm), for example, from 5 wt. %, 10 wt. %, 15 wt. % to 20 wt. %, 25 wt. %, 30 wt. %, or within any range using any two of the foregoing as endpoints, such as 5 wt. % to 30 wt. %, 10 wt. % to 25 wt. %, or 15 wt. % to 20 wt. %, where wt. % is based on the total weight of the diamond-containing filler.

One component of the diamond-containing filler may be aluminum oxide (D50 10-15 μm). The aluminum oxide may have a D50 particle size from 10 μm, 12 μm to 14 μm, 15 μm, or within any range using any two of the foregoing as endpoints, such as 10 μm to 15 μm, or 12 μm to 14 μm, as measured by a Mastersizer 3000 Laser particle size analyzer. The diamond-containing filler may comprise a weight percent of aluminum oxide (D50 10-15 μm), for example, from 5 wt. %, 7 wt. %, 9 wt. % to 11 wt. %, 13 wt. %, 15 wt. %, or within any range using any two of the foregoing as endpoints, such as 5 wt. % to 15 wt. %, 7 wt. % to 13 wt. %, or 9 wt. % to 11 wt. %, where wt. % is based on the total weight of the diamond-containing filler.

One component of the diamond-containing filler may be aluminum oxide (D50 25-45 μm). The aluminum oxide may have a D50 particle size from 25 μm, 30 μm to 35 μm, 45 μm or within any range using any two of the foregoing as endpoints, such as 25 μm to 45 μm, or 30 μm to 35 μm, as measured by a Mastersizer 3000 Laser particle size analyzer. The diamond-containing filler may comprise a weight percent of aluminum oxide (D50 25-45 μm), for example, from 30 wt. %, 40 wt. %, 45 wt. % to 50 wt. %, 60 wt. %, 65 wt. %, or within any range using any two of the foregoing as endpoints, such as 30 wt. % to 65 wt. %, 40 wt. % to 60 wt. %, or 45 wt. % to 50 wt. %, where wt. % is based on the total weight of the diamond-containing filler.

One component of the diamond-containing filler may be aluminum nitride. The aluminum nitride may have a D50 particle size from 80 μm, 90 μm to 100 μm, 120 μm or within any range using any two of the foregoing as endpoints such as 80 μm to 120 μm, or 90 μm to 100 μm, as measured by a Mastersizer 3000 Laser particle size analyzer. The diamond-containing filler may comprise a weight percent of aluminum nitride, for example, from 40 wt. %, 45 wt. %, 50 wt. %, to 55 wt. % 60 wt. %, 65 wt. %, or within any range using any two of the foregoing as endpoints, such as 40 wt. % to 65 wt. %, 45 wt. % to 60 wt. %, or 50 wt. % to 55 wt. %, is based on the total weight of the diamond-containing filler.

One component of the diamond-containing filler may be diamond (D50 80-100 μm). The diamond may have a D50 particle size from 80 μm, 85 μm to 90 μm, 100 μm or within any range using any two of the foregoing as endpoints such as 80 μm to 100 μm, or 85 μm to 90 μm, as measured by a Mastersizer 3000 Laser particle size analyzer. The diamond-containing filler may comprise a weight percent of diamond (D50 80-100 μm), for example, from 2 wt. %, 4 wt. %, 5 wt. %, to 6 wt. % 8 wt. %, 10 wt. %, or within any range using any two of the foregoing as endpoints, such as 2 wt. % to 10 wt. %, 4 wt. % to 8 wt. %, or 5 wt. % to 6 wt. %, is based on the total weight of the diamond-containing filler.

One component of the diamond-containing filler may be diamond (D50 110-130 μm). The diamond may have a D50 particle size from 110 μm, 115 μm to 120 μm, 130 μm within any range using any two of the foregoing as endpoints such as 110 μm to 130 μm, or 115 μm to 120 μm, as measured by a Mastersizer 3000 Laser particle size analyzer. The diamond-containing filler may comprise a weight percent of diamond (D50 110-130 μm), for example, from 5 wt. %, 7 wt. %, 9 wt. %, to 11 wt. % 13 wt. %, 15 wt. %, or within any range using any two of the foregoing as endpoints, such as 5 wt. % to 15 wt. %, 7 wt. % to 13 wt. %, or 9 wt. % to 11 wt. %, is based on the total weight of the diamond-containing filler.

The thermal interface material composition provided by the present disclosure can comprise a weight percent of a diamond-containing filler, for example, from 90 wt. %, 92 wt. %, 94 wt. % to 96 wt. %, 97 wt. % 98 wt. %, or within any range using any two of the foregoing as endpoints, where wt. % is based on the total weight of the TIM composition. For example, the thermally conductive filler may comprise from 90 wt. % to 98 wt. %, from 92 wt. % to 97 wt. %, or 94 wt. % to 96 wt. %.

The thermally conductive filler(s) may be selected based upon average particle size. For instance, a smaller particle size may be selected based upon a desired higher fill density and result in a higher coating performance for the TIM composition. In this case, the thermally conductive filler can have an average particle size of as little as 0.1 microns, 1 micron, 10 microns, as great as 50 microns, 75 microns, or 100 microns or within any range defined between any two of the foregoing values.

### B. Silicone Oil

The present disclosure provides a matrix for a TIM material that includes at least one long chain silicone oil. The silicone oil may include one or more crosslinkable groups, such as vinyl and hydride functional groups, that are crosslinked by a catalyst. The silicone oil may include long chain alkyl silicone oils, vinyl terminated alkyl silicone oils, and single-end hydroxyl terminated silicone oils. The silicone oil may wet the thermally conductive filler and forms a dispensable fluid for the TIM.

As discussed herein, the “long chain” silicone oils include at least one branched chain or an alkyl branched chain that extends from the main chain and vary in number of carbons. The alkyl branches have a general formula of:

CₓH₂ₓ₊₁

where x is an integer greater than 1. In some embodiments, x is as low as 2, 4, 6, 8, 10, 12, as great as 16, 18, 20, 24, 28, 32, or within any range defined between any two of the foregoing values, such as between 2 and 32, between 6 and 16, and between 4 and 12. The branched silicone oil can achieve a lower viscosity with less molecular chain entanglement compared with silicone oils having the same molecular weight without the alkyl branch. The lower viscosity helps to achieve high loading of the thermally conductive fillers in the thermal interface materials formulation especially for high molecular weight silicone oils (i.e., a higher molecular weight means longer Si—O—Si chain and greater molecular chain entanglement).

In one exemplary embodiment, the silicone oil includes a silicone rubber such as the KE series products available from Shin-Etsu, such as SILBIONE® available from Bluestar, such as ELASTOSIL®, SilGel®, SILPURAN®, and SEMICOSIL® available from Wacker, such as Silopren® available from Momentive, such as Dow Corning®, Silastic®, XIAMETER®, Syl-Off® and SYLGARD® available from Dow Corning, such as SQUARE® available from Square Silicone, such as Andril® available from AB specialty Silicones. Other polysiloxanes are available from Wacker, Shin-etsu, Dowcoring, Momentive, Bluestar, RUNHE, AB Specialty Silicones, Gelest, and United Chemical Technologies.

The thermal interface material composition provided by the present disclosure can comprise a total weight percentage of a silicone oil from, for example, 1 wt. %, 2.5 wt. %, 3 wt. % to 4 wt. %, 4.5 wt. %, 5 wt. % or within any range using any two of the foregoing as endpoints, where wt. % is based on the total weight of the thermal interface material composition. For example, the thermal interface material may comprise from 1 wt. % to 5 wt. %, 2.5 wt. % to 4.5 wt. %, or 3 wt. % to 4 wt. %. In one embodiment, the thermal interface material may comprise from 2.5 wt. % to 4.5 wt. %.

i. Long Chain Alkyl Silicone Oil

The TIM may include a long chain alkyl silicone oil. The long chain alkyl silicone oil may provide lubricity between molecular chains and decreases entanglement of the molecular chains of the formulation. Exemplary long chain alkyl silicone oils may be a kind of simethicone whose partial methyl groups are replaced by a long chain alkyl group. Exemplary long chain alkyl silicone oils may have a general formula as shown below:

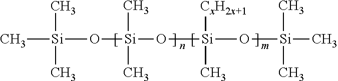

In the general formula shown above, n may range from as little as 0, 10, 50, 100, 500, as great as 1000, 2000, 5000, 10000, or within any range defined between any two of the foregoing values; x is as low as 2, 4, 6, 8, 10, 12, as great as 16, 18, 20, 24, 28, 32, or within any range defined between any two of the foregoing values, such as between 2 and 32, between 6 and 16, and between 4 and 12, and m ranges from 5, 10, 50, 200, or as great as 500, 1000, 2000, 5000, or within any range defined between any two of the foregoing values. In addition, n+m ranges from as little as 10, 30, 50, 100, 200, 500, or great as 1000, 2000, 5000, 10000, 15000, or within any range defined between any two of the foregoing values, such as between 10 and 15000, between 1000 and 5000 and between 500 and 2000. In one exemplary embodiment, x ranges from between 4 and 16. In another exemplary embodiment, x ranges from between 5 and 15. In another exemplary embodiment, x ranges from between 7 and 11. In one exemplary embodiment, n ranges from between 50 and 100. In another exemplary embodiment, n ranges from between 100 and 500. In another exemplary embodiment, n ranges from between 500 and 1000. In one exemplary embodiment, m ranges from between 10 and 100. In another exemplary embodiment, m ranges from between 100 and 500. In one exemplary embodiment, n+m ranges from between 50 and 200. In another exemplary embodiment, n+m ranges from between 200 and 1000.

Exemplary long chain alkyl silicone oils may include: polydimethylsilicone oil, BALD-BD1206 (the viscosity is 500 cst) is available from Baoerde, RH-8206 (the viscosity is 900 cst^{˜}1500 cst) and RH-8207A (the viscosity is 1000 cst^{˜}1500 cst) each is available from Runhe, YD-8206 (the viscosity is 300^{˜}2500 cst) is available from Ailidi, OFX0203 (the viscosity is 1000 cst^{˜}1500 cst) is available from Dow corning, BS-220 (the viscosity is 5000 cst) is available from Blue silane.

Exemplary long chain alkyl silicone oils may have a weight (Mw) average molecular weight as little as 1000 Daltons, 9000 Daltons, 20000 Daltons, as great as 30000 Daltons, 100000 Daltons, 200000 Daltons, or within any range defined between any two of the foregoing values, as determined by Gel Permeation Chromatography (GPC).

Exemplary long chain alkyl silicone oils may have a kinematic viscosity of 10 cSt, 50 cSt, 100 cSt to 200 cSt, 500 cSt, 1000 cSt, or within any range defined between any two of the foregoing values as measured according to ASTM D445, such as 10 cSt to 1000 cSt, 50 cSt to 500 cSt, or 100 cSt to 200 cSt. In one exemplary embodiment, an exemplary long chain alkyl silicone oil has a kinematic viscosity of between 50 cSt and 200 cSt.

The thermal interface material composition may comprise an amount of one or more long chain alkyl silicone oils from, 0.5 wt. %, 1 wt. %, 1.5 wt. % to 2 wt. %, 2.5 wt. %, 3 wt. % or within any range using any two of the foregoing as endpoints, where wt. % is based on the total weight of the thermal interface material composition, such as 0.5 wt. % to 3 wt. %, 1 wt. % to 2.5 wt. %, or 2 wt. % to 2.5 wt. %.

ii. Long Chain, Vinyl Terminated Alkyl Silicone Oil

Another exemplary long chain silicone oil of the TIM may include a long chain, vinyl terminated alkyl silicone oil. The long chain, vinyl terminated alkyl silicone oil can form a cross linked matrix with a cross linker via its terminated vinyl functional groups. Exemplary long chain, vinyl terminated alkyl silicone oils may have a general formula shown below:

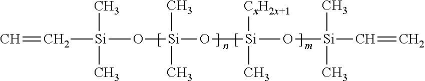

In the general formula shown above, n may range from as little as 0, 10, 50, 100, 200, 500, as great as 1000, 2000, 5000, 10000, or within any range defined between any two of the foregoing values; x is as low as 2, 4, 6, 8, 10, 12, as great as 16, 18, 20, 24, 28, 32, or within any range defined between any two of the foregoing values, such as between 2 and 32, between 6 and 16, and between 4 and 12, and m ranges from 5, 10, 50, 200, or as great as 500, 1000, 2000, 5000, or within any range defined between any two of the foregoing values. In addition, n+m ranges from as little as 10, 30, 50, 100, 200, 500, or great as 1000, 2000, 5000, 10000, 15000, 20000, or within any range defined between any two of the foregoing values, such as between 10 and 20000, between 1000 and 5000 and between 500 and 2000. In one exemplary embodiment, x ranges from between 4 and 16. In another exemplary embodiment, x ranges from between 5 and 15. In another exemplary embodiment, x ranges from between 7 and 11. In one exemplary embodiment, n ranges from between 200 and 500. In another exemplary embodiment, n ranges from between 1000 and 3000. In another exemplary embodiment, n ranges from between 2000 and 5000. In one exemplary embodiment, m ranges from between 150 and 300. In another exemplary embodiment, m ranges from between 300 and 500. In another exemplary embodiment, m ranges from between 500 and 1500. In one exemplary embodiment, n+m ranges from between 200 and 1000. In another exemplary embodiment, n+m ranges from between 1000 and 5000. In another exemplary embodiment, n ranges from between 50 and 200.

Vinyl functional silicone oils may include an organo-silicone component with Si—CH═CH2 groups. Exemplary vinyl functional silicone oils may include vinyl-terminated silicone oils and vinyl-grafted silicone oils in which the Si—CH═CH2 group is grafted onto the polymer chain, and combinations thereof.

Exemplary vinyl-terminated silicone oils may include vinyl terminated polydimethylsiloxane, such as DMS-V00 (having a weight average molecular weight (Mw) of 186 Daltons), DMS-V03 (having a Mw of about 500 Daltons), DMS-V05 (having a Mw of about 800 Daltons), DMS-V21 (having a Mw of about 6,000 Daltons), DMS-V22 (having a Mw of about 9400 Daltons), DMS-V25 (having a Mw of about 17,200 Daltons), DMS-V25R (having a Mw of about 17,200 Daltons), DMS-V35 (having a Mw of about 49,500 Daltons), DMS-V35R (having a Mw of about 49,500 Daltons), each available from Gelest, Inc. Exemplary vinyl-terminated silicone oils may include vinyl terminated diphenylsiloxane-dimethylsiloxane copolymer, such as PDV-0325 (having a Mw of about 15,500 Daltons), PDV-0331 (having a Mw of about 27,000 Daltons), PDV-0525 (having a Mw of about 14,000 Daltons), PDV-1625 (having a Mw of about 9,500 Daltons), PDV-1631 (having a Mw of about 19,000 Daltons), PDV-2331 (having a Mw of about 12,500 Daltons), each available from Gelest, Inc. Exemplary vinyl-terminated silicone oils may include vinyl terminated polyphenylmethylsiloxane, such as PMV-9925 (having a Mw of about 2000-3000 Daltons) available from Gelest, Inc. Exemplary vinyl-terminated silicone oils may include vinyl terminated diethylsiloxane-dimethylsiloxane copolymer, such as EDV-2025 (having a Mw of about 16,500-19,000 Daltons) available from Gelest, Inc.

Exemplary vinyl-terminated silicone oils may include vinyl terminated polydimethylsiloxane, such as DMS-V41 (having a Mw of about 62,700 Daltons), DMS-V42 (having a Mw of about 72,000 Daltons), DMS-V46 (having a Mw of about 117,000 Daltons), DMS-V51 (having a Mw of about 140,000 Daltons), and DMS-V52 (having a Mw of about 155,000 Daltons), each available from Gelest, Inc.

Exemplary vinyl-grafted silicone oils may include vinylmethylsiloxane homopolymers, such as VMS-005 (having a Mw of about 258-431 Daltons), VMS-T11 (having a Mw of about 1000-1500 Daltons), both available from Gelest, Inc. Exemplary vinyl-grafted silicone oils include vinylmethylsiloxane-dimethylsiloxane copolymers, such as trimethylsiloxyl terminated silicone oils, silanol terminated silicone oils, and vinyl terminated silicone oils.

Exemplary vinyl-grafted silicone oils may include vinylmethylsiloxane terpolymers, such as a vinylmethylsiloxane-octylmethylsiloxane-dimethylsiloxane terpolymer, and vinylmethylsiloxane-dimethylsiloxane copolymers, such as trimethylsiloxyl terminated silicone oils, silanol terminated silicone oils, and vinyl terminated silicone oils.

In one exemplary embodiment, the vinyl-grafted silicone oil is a vinylmethylsiloxane terpolymers. In one exemplary embodiment, the vinyl-functional silicone oil comprises a vinyl T resin or a vinyl Q resin.

In one exemplary embodiment, the silicone oil is a vinyl functional oil, such as RH-Vi303, RH-Vi301 from RUNHE, such as Andril® VS 200, Andril® VS 1000 from AB Specialty Silicones.

Exemplary long chain, vinyl terminated alkyl silicone oils may have a weight (Mw) average molecular weight as little as 1000 Daltons, 9000 Daltons, 20000 Daltons, as great as 30000 Daltons, 100000 Daltons, 200000 Daltons, or within any range defined between any two of the foregoing values, as determined by Gel Permeation Chromatography (GPC).

Exemplary long chain, vinyl terminated alkyl silicone oils may have a kinematic viscosity of 10 cSt, 50 cSt, 100 cSt to 200 cSt, 400 cSt, 500 cSt, or within any range defined between any two of the foregoing values as measured according to ASTM D445, such as 10 cSt to 500 cSt, 50 cSt to 400 cSt, or 100 cSt to 200 cSt. In one exemplary embodiment, an exemplary long chain vinyl terminated alkyl silicone oil has a kinematic viscosity of between 50 cSt and 200 cSt.

The thermal interface material composition may comprise an amount of one or more long chain, vinyl terminated alkyl silicone oils from, 0.25 wt. %, 0.5 wt. %, 1 wt. % to 1.5 wt. %, 2 wt. %, 2.5 wt. % or within any range using any two of the foregoing as endpoints, where wt. % is based on the total weight of the thermal interface material composition, such as 0.25 wt. % to 2.5 wt. %, 0.5 wt. % to 2 wt. %, or 1 wt. % to 1.5 wt. %.

### C. Dispersant

The thermal interface material may further comprise a dispersant. The dispersant may provide wettability of the thermally conductive fillers and prevent potential evaporation of the silicone oil during curing or other processing of the formulation. The dispersant may also reduce the friction between thermally conductive fillers.

The dispersant may be a long chain, single end hydroxyl terminated silicone oil. Exemplary long chain, single end hydroxyl terminated silicone oil dispersants may have a general formula as shown below:

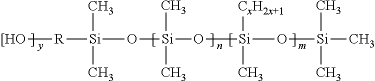

In the general formula shown above, n may range from as little as 5, 10, 50, 100, 500, as great as 1000, 2000, 5000, 10000, or within any range defined between any two of the foregoing values; x is as low as 2, 4, 6, 8, 10, 12, as great as 16, 18, 20, 24, 28, 32, or within any range defined between any two of the foregoing values, such as between 2 and 32, between 6 and 16, and between 4 and 12, and m ranges from 0, 5, 10, 50, 100, 200, or as great as 500, 1000, 2000, 5000, or within any range defined between any two of the foregoing values, such as between 5 and 5000, between 5 and 50, and between 50 and 500. In addition, n+m ranges from as little as 10, 30, 50, 100, 200, 500, or great as 1000, 2000, 5000, 10000, 15000, or within any range defined between any two of the foregoing values, such as between 10 and 10000, between 1000 and 5000 and between 500 and 2000. In one exemplary embodiment, x ranges from between 4 and 16. In another exemplary embodiment, x ranges from between 5 and 15. In another exemplary embodiment, x ranges from between 7 and 11. In one exemplary embodiment, n ranges from between 10 and 100. In another exemplary embodiment, n ranges from between 100 and 500. In another exemplary embodiment, n ranges from between 500 and 2000. In another exemplary embodiment, n ranges from between 2000 and 5000. In another exemplary embodiment, n ranges from between 5000 and 10000. In one exemplary embodiment, m is 0. In another exemplary embodiment, m ranges from between 1 and 20. In another exemplary embodiment, m ranges from between 10 and 100. In another exemplary embodiment, m ranges from between 50 and 500, y is ranges from between 1 and 3, and R is hydrocarbon group. When the molecular weight of the single end hydroxyl terminated silicone oil is not higher than 10000 Daltons, or the loading of single end hydroxyl terminated silicone oil into the final thermal interface materials is not higher than 2 wt. % and m can be 0. In one exemplary embodiment, m+n ranges from between 10 and 100. In another exemplary embodiment, m+n ranges from between 100 and 500 In another exemplary embodiment, m+n ranges from between 500 and 2000. In another exemplary embodiment, m+n ranges from between 2000 and 5000. In another exemplary embodiment, m+n ranges from between 5000 and 10000.

Hydroxyl value is a measure of the content of free hydroxyl groups in a chemical substance, usually expressed in units of mass of potassium hydroxide (KOH), in milligrams, equivalent to the hydroxyl content of one gram of the chemical substance. In a general analytical method, the hydroxyl value (mg KOH/g) is defined as the mass of potassium hydroxide, in milligrams, required to neutralize the acetic acid undergoing taken up on acetylation of one gram of the long chain, single end hydroxyl terminated silicone oils. The traditional, analytical method used to determine hydroxyl value involves acetylation of the free hydroxyl groups of the substance with acetic anhydride in a pyridine solvent. After completion of the reaction, water is added, and the remaining unreacted acetic anhydride is converted to acetic acid and measured by titration with potassium hydroxide. The hydroxyl value can be calculated using the following equation below.

HV=[56.1*N*(V_{B}−V_{acet})]/W_{acet}

where HV is the hydroxyl value; V_{B} is the amount (mL) of potassium hydroxide solution required for the titration of the blank; V_{acet} is the amount (mL) of potassium hydroxide solution required for the titration of the acetylated sample; W_{acet} is the weight of sample (in grams) used for acetylation; N is the normality of the titrant; 56.1 is the molecular weight of potassium hydroxide.

Exemplary long chain, single end hydroxyl terminated silicone oils may have a hydroxyl value as little as 0.001 mg KOH/g, 0.01 mgKOH/g, 0.1 mgKOH/g, 1 mgKOH/g, 5 mgKOH/g, as great as 10 mgKOH/g, 20 mgKOH/g, 50 mgKOH/g, 100 mgKOH/g, or within any range defined between any two of forgoing values, such as 0.01 mgKOH/g to 100 mgKOH/g, 1 mgKOH/g to 5 mgKOH/g, 1 mgKOH/g to 50 mgKOH/g, as determined by general KOH (potassium hydroxide) titration method. In one exemplary embodiment, an exemplary long chain, single end hydroxyl terminated silicone oil has a hydroxyl value range of 5 mgKOH/g to 35 mgKOH/g.

Exemplary long chain, single end hydroxyl terminated silicone oils may have a weight (Mw) average molecular weight of 500 Daltons, 1000 Daltons, 2000 Daltons to 3000 Daltons, 4000 Daltons, 5000 Daltons, or within any range defined between any two of the foregoing values, as determined by Gel Permeation Chromatography (GPC), such as 500 Daltons to 5000 Daltons, 1000 Daltons to 4000 Daltons, or 2000 Daltons to 3000 Daltons.

Exemplary long chain, single end hydroxyl terminated silicone oils may have a kinematic viscosity of 10 cSt, 50 cSt, 100 cSt to 200 cSt, 400 cSt, 500 cSt, or within any range defined between any two of the foregoing values as measured according to ASTM D445, such as 10 cSt to 500 cSt, 50 cSt to 400 cSt, or 100 cSt to 200 cSt.

The thermal interface material composition may comprise an amount of one or more long chain, single end hydroxyl terminated silicone oils from, 0.5 wt. %, 1 wt. %, 1.25 wt. % to 1.5 wt. %, 1.75 wt. %, 2 wt. % or within any range using any two of the foregoing as endpoints, where wt. % is based on the total weight of the thermal interface material composition, such as 0.5 wt. % to 2 wt. %, 1 wt. % to 1.75 wt. %, or 1.25 wt. % to 1.5 wt. %. In one exemplary embodiment, the thermal interface material comprises 0.5 wt. % to 1 wt. % of long chain, single end hydroxyl terminated silicone oil dispersant.

### D. Crosslinker

In exemplary embodiments, the TIM may include a crosslinker to enable crosslinking between silicone oils. The crosslinker may comprise a cross linking silicone oil.

The cross linking silicone oil may include Si—H groups. Exemplary silicone oils may include a hydrosilicone oil having a general formula as shown below. Exemplary hydrosilicone oils function as a cross linker in the addition reaction with the primary silicone oils.

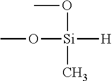

The cross linking silicone oil may include one or both sides of hydrogen-containing silicone oil and end-side hydrogen-containing silicone oil. Exemplary silicone oils may include hydrogenated silicone oils having the general formulas shown below. Exemplary hydrogenated silicone oils are used as crosslinkers in addition reactions with primary silicone oils.

### Both Sides Hydrogen-Containing Silicone Oil Formula

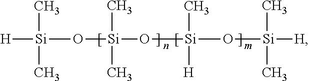

### End-Side Hydrogen-Containing Formula

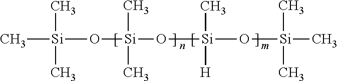

The mole ratio of Si—H groups in cross linking silicone oil may be tested by iodometric titration. Iodometric titration includes: weighing about 0.1 grams of hydride silicone oil in a tinfoil surrounded conical flask. 20 mL carbon tetrachloride (CCl4) is added into the flask to dissolve the silicone oil. and the flask is further sealed to avoid light exposure. Then, excess bromine acetic acid solution (with an availability ratio of about 10 mL) is added into the flask along with 10 mL of water. The flask is further sealed to avoid light exposure. After thirty minutes, the seal is opened and 25 ml 10% wt potassium iodide (KI) aqueous solution is added to the solution. The solution is then vibrated for 1 to 2 minutes. Then, a standard 0.1 mol/L sodium thiosulfate (Na2S2O3) aqueous solution is added to titrate the sample solution with vibration. 1 mL of a 1 wt. % starch aqueous solution is added to the solution as an indicator. When the color of the solution (e.g., blue) changes, titration is stopped and the consumption of sodium thiosulfate is calculated. This process is then repeated for other samples. To prepare a control sample, the process is repeated with no silicone oil. The content of Si—H groups (mmol/g) is as following

N2=[(V_{d}−V_{c})*M2]/G2

wherein: N2 is the mole ratio of Si—H groups (mmol/g); V_{d} is the volume (ml) of sodium thiosulfate solution titration for hydride silicone oil sample; V_{c} is the volume (ml) of sodium thiosulfate solution titration for blank sample; G2 is the weight (g) of hydride silicone oil; M2 is the mole concentration (mol/l) of the standard sodium thiosulfate solution.

The mole ratio of Si—H groups (mmol/g) in silicone oil may be 0.01 mmol/g, 0.05 mmol/g, 0.10 mmol/g, to 0.15 mmol/g, 0.20 mmol/g, 0.35 mmol/g, or within any range defined between any two of the foregoing values, such as 0.05 mmol/g to 0.35 mmol/g, 0.10 mmol/g to 0.20 mmol/g, or 0.15 mmol/g to 0.20 mmol/g. In one exemplary embodiment, the mole ratio of Si—H groups is in the amount of 0.05 mmol/g to 0.15 mmol/g.

Exemplary cross linking silicone oils may have a kinematic viscosity of 0.5 mm²/s, 1 mm²/s, 10 mm²/s to 100 mm²/s, 250 mm²/s, 500 mm²/s, or within any range defined between any two of the foregoing values as measured according to ASTM D445, such as 0.5 mm²/s to 500 mm²/s, 1 mm²/s to 250 mm²/s, or 10 mm²/s to 100 mm²/s. In one exemplary embodiment, the cross linking silicone oil has a kinematic viscosity between 100 mm²/s and 200 mm²/s.

In some exemplary embodiments, the TIM comprises the one or more crosslinkers in an amount from 0.05 wt. %, 0.10 wt. %, 0.15 wt. % to 0.20 wt. %, 0.25 wt. %, 0.30 wt. %, or within any range defined between any two of the foregoing values, based on the total weight of the thermal interface material, such as 0.05 wt. % to 0.30 wt. %, 0.10 wt. % to 0.25 wt. %, or 0.15 wt. % to 0.20 wt. %. In one exemplary embodiment, the TIM comprises 0.20 wt. % to 0.30 wt. % of crosslinkers.

The ratio of total Si—H group content (T_{Si—H}, mmol) to the total vinyl content (T_{vinyl}) may be calculated by the equation:

T_{Si—H}/T_{vinyl}.

The TIM may comprise a ratio of Si—H group content to total vinyl content from 0.01, 0.1, 0.5 to 1.0, 1.5, 2.0, or within any range defined between any two of the foregoing values, such as 0.01 to 2.0, 0.1 to 1.5, or 0.5 to 1.0. In one exemplary embodiment, the ratio of Si—H group content to total vinyl content is 0.1 to 1.0. In another exemplary embodiment, the ratio of Si—H group content to total vinyl content is 0.1 to 0.5.

### E. Catalyst

The TIM may further include one or more catalyst for catalyzing the addition reaction. Exemplary catalysts comprise platinum containing materials and rhodium containing materials.

Exemplary catalysts may comprise platinum containing materials and rhodium containing materials. Exemplary platinum containing catalysts may have the general formula shown below:

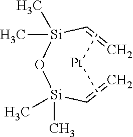

Exemplary platinum containing catalysts may include: platinum cyclovinylmethylsiloxane complex (Ashby Karstedt Catalyst), platinum carbonyl cyclovinylmethylsiloxane complex (Ossko catalyst), platinum divinyltetramethyldisiloxane dimethyl fumarate complex, platinum divinyltetramethyldisiloxane dimethyl maleate complex and the like. Exemplary platinum carbonyl cyclovinylmethylsiloxane complexes may include SIP6829.2, exemplary platinum divinyltetramethyldisiloxane complexes may include SIP6830.3 and SIP6831.2, exemplary platinum cyclovinylmethylsiloxane complexes may include SIP6833.2, all available from Gelest, Inc. Further exemplary platinum containing material catalysts may include Catalyst OL available from Wacker Chemie AG, and PC065, PC072, PC073, PC074, PC075, PC076, PC085, PC086, PC087, PC088 available from United Chemical Technologies Inc.

Exemplary rhodium containing materials may include Tris(dibutylsulfide)rhodium trichloride with product code INRH078, available from Gelest, Inc.

Without wishing to be held to any particular theory it is believed that the platinum catalyst reacts with a vinyl silicone oil and a hydrosilicone oil.

In one exemplary embodiment, the catalyst may be provided as a mixture with one or more of the silicone oils. In one exemplary embodiment, the platinum containing material catalyst may be combined to a functional silicone oil, such as KE-1012-A, KE-1031-A, KE-109E-A, KE-1051J-A, KE-1800T-A, KE1204A, KE1218A available from Shin-Etsu, such as SILBIONE® RT Gel 4725 SLD A available from Bluestar, such as SilGel® 612 A, ELASTOSIL® LR 3153A, ELASTOSIL® LR 3003A, ELASTOSIL® LR 3005A, SEMICOSIL® 961A, SEMICOSIL® 927A, SEMICOSIL® 205A, SEMICOSIL® 9212A, SILPURAN® 2440 available from Wacker, such as Silopren® LSR 2010A available from Momentive, such as XIAMETER® RBL-9200 A, XIAMETER® RBL-2004 A, XIAMETER® RBL-9050 A, XIAMETER® RBL-1552 A, Silastic® FL 30-9201 A, Silastic® 9202 A, Silastic® 9204 A, Silastic® 9206 A, SYLGARD® 184A, Dow Corning® QP-1 A, Dow Corning® C6 A, Dow Corning® CV9204 A available from Dow Corning.

The TIM may comprise the one or more catalyst in an amount of 5 ppm, 10 ppm, 50 ppm to 100 ppm, 150 ppm, 200 ppm, or within any range using any two of the foregoing as endpoints, where is based on the total weight of the silicone oil, such as 5 ppm to 200 ppm, 10 ppm to 150 ppm, or 50 ppm to 100 ppm.

### F. Inhibitor

The TIM comprises one or more inhibitors for inhibiting or limiting crosslinking of the silicone oils. The inhibitors may include at least one of an alkynyl compound and a polyvinyl functional polysiloxane. The polyvinyl functional polysiloxane may be a vinyl terminated polydimethylsiloxane. The alkynyl compound may be an alkynyl alcohol compound.

Exemplary inhibitors may include acetylenic alcohols such as 1-ethynyl-1-cyclohexanol, 2-methyl-3-butyn-2-ol, 2-phenyl-3-butyn-2-ol, 2-ethynyl-isopropanol, 2-ethynyl-butane-2-ol, and 3,5-dimethyl-1-hexyn-3-ol; silylated acetylenic alcohols such as trimethyl (3,5-dimethyl-1-hexyn-3-oxy)silane, dimethyl-bis-(3-methyl-1-butyn-oxy)silane, methylvinylbis(3-methyl-1-butyn-3-oxy)silane, and ((1,1-dimethyl-2-propynyl)oxy)trimethylsilane; unsaturated carboxylic esters such as diallyl maleate, dimethyl maleate, diethyl fumarate, diallyl fumarate, and bis-2-methoxy-1-methylethylmaleate, mono-octylmaleate, mono-isooctylmaleate, mono-allyl maleate, mono-methyl maleate, mono-ethyl fumarate, mono-allyl fumarate, 2-methoxy-1-methylethylmaleate; fumarate/alcohol mixtures, such as mixtures where the alcohol is selected from benzyl alcohol or 1-octanol and ethenyl cyclohexyl-1-ol; conjugated ene-ynes such as 2-isobutyl-1-butene-3-yne, 3,5-dimethyl-3-hexene-1-yne, 3-methyl-3-pentene-1-yne, 3-methyl-3-hexene-1-yne, 1-ethynylcyclohexene, 3-ethyl-3-butene-1-yne, and 3-phenyl-3-butene-1-yne; vinylcyclosiloxanes such as I,3,5,7-tetramethyl-1,3,5,7-tetravinylcyclotetrasiloxane, and mixtures of conjugated ene-yne and vinylcyclosiloxane. In one exemplary embodiment, the addition inhibitor is selected from 2-methyl-3-butyn-2-ol or 3-methyl-1-pentyn-3-ol.

In some exemplary embodiments, the vinyl terminated polydimethylsiloxane in ethynyl cyclohexanol may be Pt Inhibitor 88 available from Wacker Chemie AG. Without wishing to be held to any particular theory it is believed that the platinum catalyst forms a complex with ethynyl cyclohexanol and vinyl terminated polydimethylsiloxane as shown below.

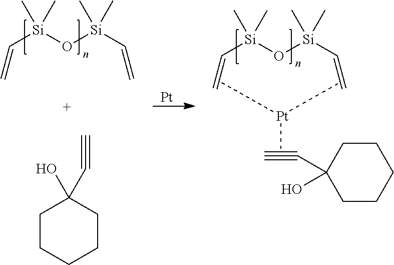

The formation of the complex is believed to decrease the catalyst activity in room temperature, and thus maintaining the dispensability and wettability of the TIM. At the higher temperatures of the curing step, the Pt is released from the complex and help the hydrosilylation of vinyl functional silicone oil and hydride functional silicone oil, provides greater control over the “crosslinking”.

In some exemplary embodiments, the TIM may comprise the one or more inhibitors in an amount from 0.01 wt. %, 0.02 wt. %, 0.05 wt. % to 0.10 wt. %, 0.25 wt. %, 0.50 wt. %, or within any range defined between any two of the foregoing values, based on the total weight of the TIM, such as 0.01 wt. % to 0.50 wt. %, 0.02 wt. % to 0.25 wt. %, or 0.05 wt. % to 0.10 wt. %. In one exemplary embodiment, the TIM comprises an amount of inhibitors from 0.01 wt. % to 0.02 wt. %.

Without wishing to be held to any particular theory, it is believed that, in the absence of an inhibitor, the vinyl functional silicone oil reacts with the hydride functional silicone oil very quickly based on the addition hydrosilylation mechanism to form a solid phase that cannot be automatically dispensed by typical methods.

### G. Release Agent

The TIM composition may comprise a releasing agent. The release agent may be used in combination with a coupling agent, discussed further below. The combination of a releasing agent and coupling agent may increase the dispense rate of the TIM in a syringe and play a role in lubrication.

A release agent may be an interface coating used on two surfaces that tend to stick to each other to make the surface easy to release, smooth and clean. The specific action principle of the release agent used in the mold casting of the TIM may be as follows. Polar chemical bonds of the TIM interact with the surface of a mold to form an adsorption film with regenerative power. The silicon-oxygen bond in polysiloxane can be regarded as a weak dipole (Si+—O—). When the release agent spreads on the surface of the mold into a single orientation arrangement, the molecules may adopt a unique extended chain configuration. The free surface may be covered by the alkyl group in a densely packed manner, and the release ability may increase with the density of the alkyl group. However, when the alkyl group occupies a large steric hindrance, the extended configuration may be restricted, and the release ability may decrease.

The molecular weight and viscosity of the release agent may also be related to the releaseability of the TIM. When the molecular weight of the release agent is small, the spreadability may be good, but the heat resistance may be poor. According to active substances, it can be divided into six series: (1) silicon series—mainly siloxane compounds, silicone oil, silicone resin methyl branched silicone oil, methyl silicone oil, emulsified methyl silicone oil, hydrogen-containing methyl silicone oil, silicone grease, silicone resin, silicone rubber, silicone rubber toluene solution; (2) wax series—plant, animal, synthetic paraffin; microcrystalline paraffin; polyethylene wax, etc; (3) fluorine series—the best isolation performance, less pollution to the mold, but high cost polytetrafluoroethylene; fluororesin powder; fluororesin coating, etc.; (4) surfactant series—metal soap (anionic), EO, PO derivatives (nonionic); (5) inorganic powder series—talc, mica, clay, white clay, etc.; (6) polyether series—a mixture of polyether and grease, with good heat resistance and chemical properties, and is mostly used in some rubber industries that have restrictions on silicone oil. The cost is higher than that of silicone oil series.

The release agent may be alkyl ester polydimethylsiloxane. The alkyl ester polydimethylsiloxane release agent may have a weight (Mw) average molecular weight as little as 8000 Daltons, 10000 Daltons, as great as 20000 Daltons, 30000 Daltons, or within any range defined between any two of the foregoing values, as determined by Gel Permeation Chromatography (GPC).

The TIM may comprise one more release agent in an amount from as 0 wt. %, 0.1 wt. %, 0.2 wt. % to 0.4 wt. %, 0.5 wt. %, 0.6 wt. %, or within any range defined between any two of the foregoing values, based on the total weight of the TIM, such as 0 wt. % to 0.6 wt. %, 0.1 wt. % to 0.5 wt. %, or 0.2 wt. % to 0.4 wt. %. In one exemplary embodiment, the TIM includes a release agent in the amount of about 0.4 wt. %.

### H. Coloring Agent/Pigment

The thermal interface material may comprise a coloring agent/pigment, such as inorganic pigments.

In some exemplary embodiments, the coloring agent is an inorganic pigment selected from the group consisting of α-Fe₂O₃; α-Fe₂O₃·H₂O; and Fe₃O₄.

In some exemplary embodiments, the coloring agent is an organic pigment. In a more particular embodiment, the coloring agent is Fe₃O₄, such as such as commercially available Iron Black.

In some exemplary embodiments, the TIM comprises pigment in an amount from 0.01 wt. %, 0.02 wt. %, 0.04 wt. % to 0.06 wt. %, 0.08 wt. %, 0.10 wt. %, or within any range defined between any two of the foregoing values, based on the total weight of the TIM, such as 0.01 wt. % to 0.10 wt. %, 0.02 wt. % to 0.08 wt. %, or 0.04 wt. % to 0.06 wt. %.

### I. Coupling Agent

The thermal interface material composition provided by the present disclosure may comprise one or more coupling agents. Exemplary coupling agents include silane coupling agents with general formula Y—(CH₂)n-Si—X3, wherein Y is organofunctional group, X is hydrolysable group. Organofunctional group Y includes alkyl, glycidoxy, acryloxyl, methylacryloxyl, amine, or a combination thereof. Hydrolysable group X includes alkyloxy, acetoxy. In some exemplary embodiments, the silane coupling agent includes alkyltrialkoxysilanes. Exemplary alkytrialkoxy silane comprise decyltrimethoxylsilane, undecyltrimethoxylsilane, hexadecyltrimethoxysilane, octadecyltrimethoxysilane, or dodecyltrimethyloxysilane. In one exemplary embodiment, the TIM includes dodecyltrimethyloxysilane as the coupling agent as shown in the formula below.

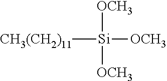

The coupling agent may increase the dispersion and wettability of the TIM composition.

The thermal interface material composition provided by the present disclosure can comprise a weight percent of one or more coupling agents of, for example, from 0 wt. %, 0.02 wt. %, 0.04 wt. % to 0.08 wt. %, 0.10 wt. %, 0.12 wt. % or within any range using any two of the foregoing as endpoints, where wt. % is based on the total weight of the TIM composition. For example, the one or more coupling agents may comprise from 0 wt. %. to 0.12 wt. %, from 0.02 wt. % to 0.10 wt. %, from 0.04 wt. % to 0.08 wt. % of the total weight of the TIM composition.

### II. Properties of the Thermally Conductive Hybrid Thermal Interface Material

### A. Thermal Conductivity

The thermal conductivity of a material describes the rate at which heat is transferred by conduction through a unit cross-section area of a material. Thermal interface material is used to conduct heat away from electrical components to a heat spreader. This allows for an electrical component to avoid overheating or damaging due to heat during use.

The thermal interface material of the present disclosure may exhibit relatively high thermal conductivity. For example, a thermally conductive hybrid thermal interface material provided by the present disclosure can comprise a thermal conductivity, for example, from 7 W/(m·k), 8 W/(m·k), 9 W/(m·k) to 10 W/(m·k), 11 W/(m·k), 12 W/(m·k), 13 W/(m·k), 14 W/(m·k), or within any range using any two of the foregoing as endpoints, as determined per ASTM D5470. For example, the thermal conductivity may comprise between 7 W/(m·k) and 14 W/(m·k), 8 W/(m·k) and 13 W/(m·k), 9 W/(m·k) and 12 W/(m·k), and 10 W/(m·k) and 11 W/(m·k). In one exemplary embodiment, the thermal interface material exhibits a thermal conductivity of 13 W/(m·k), as determined per ASTM D5470.

Thermal impedance (TI) testing characterizes the ability of a composition to diffuse heat from one electrical component to the remainder of the electrical device. Gallium-based thermal interface materials provided by the present disclosure can comprise a TI, for example, within a range from 0.01 or 0.06 C ° C. cm2/W as determined per ASTM D5470. In one exemplary embodiment, the thermal interface material exhibits a thermal impedance of 0.30 to 0.65 C ° C. cm2/W, as measured by ASTM D5470.

### B. Vertical Stability

Vertical stability test may determine whether the TIM material will crack and slip and experience oil bleeding (or separation of material components) during the application of the device. To test vertical stability, the TIM material may be added between a panel of glass and a panel of either aluminum or copper. The panes are exposed to temperature cycling to observe whether the TIM material cracks or slides. Traditional TIM hybrid products may have issues with dropping and cracking in temperature cycling tests. If TIM material cracks or slides, the thermal conductivity of the TIM material on the device may decrease, potentially resulting in failure of the product.

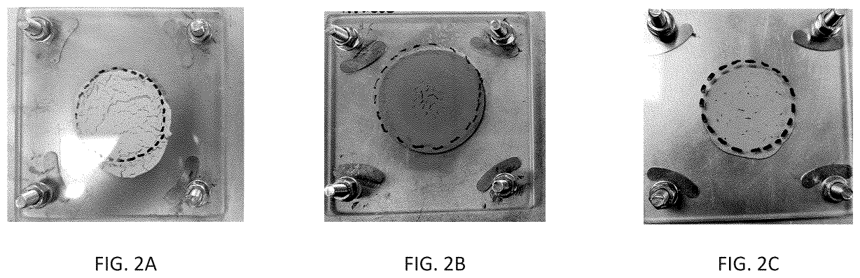

The TIM material of the present disclosure exhibits good vertical stability. For example, a thermally conductive hybrid thermal interface material provided by the present disclosure may experience an amount of TIM material sliding during a vertical stability test of less than 30%, less than 25%, less than 20% or less than 15%, or within any range using any two off the foregoing as endpoints. As shown in FIGS. 2A-2C, inventive TIM materials and comparative TIM materials were tested for vertical stability. In FIG. 2A, a comparative TIM material was tested for vertical stability as described above. The comparative TIM material had more than 20% of the TIM material cracking and sliding with no oil bleeding. As seen in FIGS. 2B and 2C, inventive TIM materials were tested and had less than 20% of the material crack or slide and no oil bleeding.

### III. Applications Utilizing the Thermal Interface Material

The thermal interface material composition provided by the present disclosure may be used as the thermal interface material in a variety of electronic components contexts.

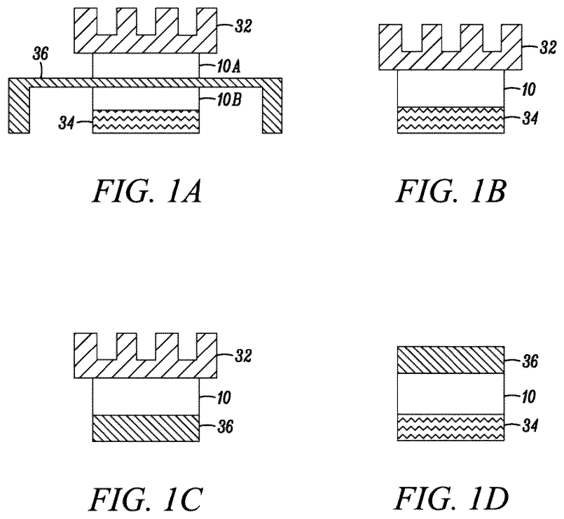

For example, FIG. 1A schematically illustrates an electronic chip 34, a heat spreader 36, and a heat sink 32 with a first thermal interface material (TIM) 10A connecting the heat sink 32 and heat spreader 36, and a second thermal interface material 10B connecting the heat spreader 36 and electronic chip 34. One or both of thermal interface materials 10A and/or 10B may be a comprise the thermally conductive hybrid thermal interface material composition described previously. FIG. 1B illustrates the exemplary thermal interface material 10 as a thermal interface layer designated as a TIM positioned between an electronic chip 34 and a heat sink 32, such that a first surface of TIM 10 is in contact with a surface of electronic chip 34 and a second surface of TIM 1 is in contact with a surface of heat sink 32. As with FIG. 1A, TIM 10 can comprise the thermally conductive hybrid thermal interface material composition described previously. FIG. 1C illustrates the exemplary thermal interface material 10 as thermal interface material positioned between a heat spreader 36 and a heat sink 32, such that a first surface of TIM 10 is in contact with a surface of heat spreader 36 and a second surface of TIM 10 is in contact with a surface of heat sink 32. As with FIGS. 1A and 1B, TIM 10 can comprise the thermally conductive hybrid thermal interface material composition described previously. FIG. 1D illustrates an exemplary thermal interface material 10 as a thermal interface material positioned between an electronic chip 34 and a heat spreader 36 such that a first surface of TIM 10 is in contact with a surface of electronic chip 34 and a second surface of TIM 10 is in contact with a surface of heat spreader 36. AS with FIGS. 1A, 1B and 1C, TIM 10 can comprise the l thermally conductive hybrid thermal interface material composition described previously.

The thermally conductive hybrid TIM of the present disclosure may be applied to a substrate using a variety of printing processes including a stencil printing process. Using a stencil can offer higher controllability and/or efficiency of the application of the TIM to electrical components. For example, by using a stencil, the TIM can be applied repeatedly in the same pattern on many components. Stencils can be made in a variety of shapes, allowing the TIM to be applied to a variety of electrical components. The TIM may be printed onto a substrate, which may be a conductive metallic substrate, such as a copper substrate or an aluminum substrate. In some cases, the conductive substrate may be a nickel coated substrate such as a nickel coated copper substrate, or a nickel coated aluminum substrate.

For example, the components of the thermally conductive hybrid TIM composition as provided by the present disclosure may be combined into a paste. The paste may be printed, such as by a squeegee and stencil process, onto a coated metal substrate, such as a nickel coated copper substrate or a nickel coated aluminum substrate. The top portion of the substrate may be overlain with a stencil, where the stencil comprises both a thickness (t) and a plurality of openings arranged as a mesh. The openings may be based upon a variety of geometries, including a hexagonal geometry, whereas each opening geometry comprises a length (l) (or diameter). A distance (a) between each of the openings about the mesh may be based upon the thickness (t) of the stencil, where the distance (a) is proportional to the (t). For example, in the case where the stencil comprises a relatively large thickness (t), the distance (a) between openings may be relatively large, or conversely, when the thickness (t) is relatively small, the distance (a) between openings also may be relatively small. The distance (a) between openings may also be proportional to the length of the opening (l), such that with larger length (l) vales, the distance between opening (a) may also relatively large. Each of the at least the variable (a), (l) and (t) may be adjusted, either alone or in combination, such that a desired thickness of the thermally conductive hybrid TIM paste is deposited onto the coated metal substrate at a desired thickness.

For example, a pattern is cut in a steel substrate using a laser or other process that results in a clean edge on the stencil geometry. Some processes such as traditional steel stamping may be avoided as they could leave a rolled edge or sharp feature that may cause the stencil not to sit flush or cause scratches in the heatsink surface. The feature size of the stencil may be small enough that the straightness of the scraper edge avoids influencing the thickness of the paste (i.e., wide openings should be avoided). A honeycomb pattern may be used n as it gives an even distribution and can easily be specified on a drawing using two dimensions. A scraper can be used to press the paste into the stencil features, and the use of a pattern enables the scraper to remain parallel to the heatsink at all points. The pattern remains on the surface until the module has been pressed down and temperature cycled, at which point, the paste flows to fill voids. The shape, size, and spacing of the holes along with the thickness of the stencil determine how thick the resulting paste is once the module is mounted.

For example, when the length of the pattern (e.g., in a honeycomb orientation) cut into the steel plate is 2.0 mm, and the space between the individual pattern cutouts is 0.5 mm, the thickness of the resulting past may be approximately 0.08 mm. In another example, when the length of the honeycomb pattern is 3.0 mm, and the space between the individual pattern cutouts is 0.75 mm, the thickness of the resulting past may be approximately 0.1 mm. In still further examples, when the length of the honeycomb pattern is 4.0 mm, and the space between the individual pattern cutouts is either 1 mm or 2 mm, the thickness of the resulting past may be approximately 0.12 mm and in a range from 0.15 mm to 0.2 mm, respectively.

### EXAMPLES

### Example 1

Two diamond-containing fillers, N21 and N23, were prepared according to the formulations in Table 1.

To prepare N21, zinc oxide, aluminum oxide, and diamond powder were weighed out in the amounts indicated in Table 1 and mixed using a speed mixer at a speed of 1200 rpm for 2 minutes. The mixture was mixed three times to obtain N21.

To prepare N23, zinc oxide, aluminum oxide, aluminum nitride, and diamond powder were weighed out in the amounts indicated in Table 1 and mixed using a speed mixer at a speed of 1200 rpm for 2 minutes. The mixture was mixed three times to obtain N23.

TABLE 1
Diamond-Containing Filler Formulations

| | | | N21 | N23 |
|---|---|---|---|---|
| | | | Range | Range |
| Component | Particle size | Category | Wt. % | Wt. % |
| zinc oxide | D50 = | Thermally conductive | 0.2~2.5 | 0.2~2.5 |
| | 0.45~0.65 μm | filler | | |
| aluminum | D50 = | Thermally conductive | 5-20 | 10~30 |
| oxide | 2~5 μm | filler | | |
| aluminum | D50 = | Thermally conductive | 0 | 5~15 |
| oxide | 10~15 μm | filler | | |
| aluminum | D50 = | Thermally conductive | 30~65 | 0 |
| oxide | 25~45 μm | filler | | |
| aluminum | D50 = | Thermally conductive | 0 | 40~65 |
| nitride | 80~120 μm | filler | | |
| diamond | D50 = | Thermally conductive | 0 | 2~10 |
| | 80~100 μm | filler | | |
| diamond | D50 = | Thermally conductive | 5~15 | 0 |
| | 110~130 μm | filler | | |

One comparative TIM composition and two inventive TIM compositions were prepared according to the formulations in Table 2.

TABLE 2
Thermally Conductive Hybrid TIM Formulations

| | Comparative 1 | Inventive 1 | Inventive 2 |
|---|---|---|---|
| Category | Wt. % | Wt. % | Wt. % |
| Silicone Oil | 1.87 | 1.83 | 1.91 |
| Dispersant | 0.83 | 0.85 | 0.85 |
| Crosslinker | 0.13 | 0.22 | 0.14 |
| Catalyst | 0.17 | 0.18 | 0.18 |
| Inhibitor | 0.02 | 0.02 | 0.02 |
| Release Agent | 0 | 0.04 | 0.04 |
| Pigment | 0 | 0.08 | 0.08 |
| N21 Diamond- | 96.98 | 0 | 96.71 |
| Containing Filler | | | |
| N23 Diamond- | 0 | 96.71 | 0 |
| Containing Filler | | | |
| Coupling Agent | 0 | 0.08 | 0.08 |

The silicone oil, dispersant, crosslinker, and inhibitor were weighed and added to a Speed Mixer at 2000 rpm for 2 minutes to create the silicone oil component.

The diamond-containing filler, coupling agent, release agents, and pigment were added silicone oil component in the Speed Mixer at 2000 rpm for 4 minutes.

The catalyst was added to the previous components in the Speed Mixer at 2000 rpm for 2 minutes.

The composition was then added to a vacuum stirring and defoaming machine for 6 minutes at a vacuum degree of −0.1 Mpa to produce the thermally conductive hybrid TIMs.

### Example 2

Each thermally conductive hybrid TIM composition, examples 1, 2, and 3, was tested for thermal resistance and thermal conductivity.

The thermal conductivity of the TIM compositions was tested using the Analysis Tech, Inc. Thermal Interface Material Tester, or “TIM Tester.” The TIM Tester measures the thermal conductivity and thermal resistance in materials having moderate to high thermal conductivity and is ideally suited for measurement of thermal interface materials used in electronic packaging. The TIM Testers conform to test method ASTM D-5470-06, where thermal impedance of a test sample is computed by dividing the temperature difference across the sample by the heat flowing through the sample.

Table 3 illustrates the thermal conductivity of each example.

TABLE 3
Thermal Conductivity and Impedance of TIM Compositions

| | Comparative 1 | Inventive 1 | Inventive 2 |
|---|---|---|---|
| Thermal | 13.2 at a | 12.2 at a | 12.1 at a |
| Conductivity | 0.80 mm gap | 0.81 mm gap | 0.72 mm gap |
| (W/m*K) | 13.3 at a | 12.8 at a | NA |
| | 0.44 mm gap | 0.55 mm gap | |
| Thermal Impedance | 0.58 at a | 0.63 at a | 0.63 at a |
| (° C.*cm²/W) | 0.80 mm gap | 0.81 mm gap | 0.81 mm gap |
| | 0.33 at a | 0.45 at a | NA |
| | 0.44 mm gap | 0.55 mm gap | |

### Example 3

Each thermally conductive hybrid TIM composition, comparative example 1, inventive example 1, and inventive example 2, was tested for vertical stability under thermal cycling. To test of vertical stability the flow rates listed in table 4 were used for each sample.

TABLE 4
Dispense Rate for Examples 1, 2, and 3

| Property | Comparative 1 | Inventive 1 | Inventive 2 |
|---|---|---|---|
| Dispense rate | 31.5 g/min | 12.0 g/min | 13.8 g/min |
| 6 oz (180 cc) cartridge | | | |
| with 3 mm plastic, | | | |
| tapered nozzle | | | |

NOTE:
To measure the flow rate of a TIM sample, a 30 cubic centimeter (cc) syringe without a nozzle is used, and the TIM sample is dispensed via dispenser tool for 1 minute under a pressure of 0.6 MPa. After 1 minute, the dispensed TIM sample is weighed.

The vertical stability of the TIM composition was tested using the method described above. The TIM composition was place between a glass and aluminum jig and put into a thermal cycling chamber at 0.8 mm gap for 1100 cycles from −40° C. to 120° C. The rise time was 10° C. per minute and swelling time was 20 minutes at peak/low temperature. Both inventive TIM compositions had less than 20% of the material crack or slide and no visible separation of material components/oil bleeding, as seen in FIGS. 2B-C. However, the comparative TIM material composition, as seen in FIG. 2A, showed more than 20% of the TIM material cracking and sliding and no oil bleeding.

What is claimed is:

1. A thermal interface material, comprising:
a diamond-containing filler;
a silicone oil; and
a plurality of additives.

2. The thermal interface material of claim 1, wherein the plurality of additives comprise:
a dispersant;
a crosslinker;
a catalyst;
an inhibitor;
a release agent;
a pigment; and
a coupling agent.

3. The thermal interface material of claim 1, wherein the diamond-containing filler comprises from 93 wt. % to 98 wt. % of the total weight of the thermal interface material.

4. The thermal interface material of claim 1, wherein the diamond-containing filler comprises:
zinc oxide;
aluminum oxide (D50=2-5 μm);
aluminum oxide (D50=25-45 μm); and
diamond (D50=110-130 μm).

5. The thermal interface material of claim 4, wherein:
zinc oxide comprises from 0.2 wt. % to 2.5 wt. % of the total weight of the diamond-containing filler;
aluminum oxide (D50=2-5 μm) comprises from 5 wt. % to 20 wt. % of the total weight of the blended diamond filler;
aluminum oxide (D50=25-45 μm) comprises from 30 wt. % to 65 wt. % of the total weight of the blended diamond filler; and
diamond (D50=110-130 μm) comprises from 5 wt. % to 15 wt. % of the total weight of the blended diamond filler.

6. The thermal interface material of claim 1, wherein the blended diamond filler comprises:
zinc oxide;
aluminum oxide (D50=2-5 μm);
aluminum oxide (D50=10-15 μm);
aluminum nitride; and
diamond (D50=80-100 μm).

7. The thermal interface material of claim 6, wherein:
the zinc oxide comprises from 0.2 wt. % to 2.5 wt. % of the total weight of the blended diamond filler;
the aluminum oxide (D50=2-5 μm) comprises from 10 wt. % to 30 wt. % of the total weight of the blended diamond filler;
the aluminum oxide (D50=10-15 μm) comprises from 5 wt. % to 15 wt. % of the total weight of the blended diamond filler;
the aluminum nitride comprises from 40 wt. % to 65 wt. % of the total weight of the blended diamond filler; and
the diamond (D50=80-100 μm) comprises from 2 wt. % to 10 wt. % of the total weight of the blended diamond filler.

8. The thermal interface material of claim 1, wherein thermal interface material has a thermal conductivity from 10 W/(m.k.) to 13 W/(m.k.), as determined per ASTM D5470.

9. The thermal interface material of claim 1, wherein the silicone oil comprises 2.5 wt. % to 4.5 wt. % of the total weight of the thermal interface material.

10. The thermal interface material of claim 2, wherein the pigment comprises 0.01 wt. % to 0.10 wt. % of the total weight of the thermal interface material.

11. A method for applying a thermal interface material to a substrate, comprising:
combining each of a conductive filler, a silicone oil, and a plurality of additives to form the thermal interface material;
wherein the conductive filler comprises a blended diamond filler; and
applying the thermal interface material to a metal substrate.

12. The method of claim 11, wherein the blended diamond filler comprises zinc oxide, aluminum oxide (D50=2-5 μm), aluminum oxide (D50=25-45 μm), and diamond (D50=110-130 μm).

13. The method of claim 11, wherein the blended diamond filler comprises zinc oxide, aluminum oxide (D50=2-5 μm), aluminum oxide (D50=10-15 μm), aluminum nitride, and diamond (D50=80-100 μm).

14. An electronic component comprising:
a heat sink;
an electronic chip; and
a thermal interface material positioned between the heat sink and the electronic chip, wherein the thermal interface material comprises:
a conductive filler
wherein the conductive filler comprises a blended diamond filler;
silicone oil; and
a plurality of additives.

15. The electronic component of claim 14, wherein the plurality of additives comprises:
a dispersant;
a crosslinker;
a catalyst;
an inhibitor;
a release agent;
a pigment; and
a coupling agent.

16. The electronic component of claim 14, wherein the thermal interface material has a thermal conductivity from 10 W/(m.k.) to 13 W/(m.k.), as determined per ASTM D5470.

17. The electronic component of claim 14, wherein the blended diamond filler comprises:
zinc oxide; and
aluminum oxide (D50=2-5 μm);
aluminum oxide (D50=25-45 μm); and
diamond (D50=110-130 μm).

18. The electronic component of claim 17, wherein:
zinc oxide comprises from 0.2 wt. % to 2.5 wt. % of the total weight of the blended diamond filler;
aluminum oxide (D50=2-5 μm) comprises from 5 wt. % to 20 wt. % of the total weight of the blended diamond filler;
aluminum oxide (D50=25-45 μm) comprises from 30 wt. % to 65 wt. % of the total weight of the blended diamond filler; and
diamond (D50=110-130 μm) comprises from 5 wt. % to 15 wt. % of the total weight of the blended diamond filler.

19. The electronic component of claim 14, wherein the blended diamond filler comprises:
zinc oxide; and
aluminum oxide (D50=2-5 μm);
aluminum oxide (D50=10-15 μm);
aluminum nitride; and
diamond (D50=80-100 μm).

20. The electronic component of claim 19, wherein:
zinc oxide comprises from 0.2 wt. % to 2.5 wt. % of the total weight of the blended diamond filler;
aluminum oxide (D50=2-5 μm) comprises from 10 wt. % to 30 wt. % of the total weight of the blended diamond filler;
aluminum oxide (D50=10-15 μm) comprises from 5 wt. % to 15 wt. % of the total weight of the blended diamond filler;
aluminum nitride comprises from 40 wt. % to 65 wt. % of the total weight of the blended diamond filler; and
diamond (D50=80-100 μm) comprises from 2 wt. % to 10 wt. % of the total weight of the blended diamond filler.
